(19) United States
(12) Patent Application Publication
(10) Pub. No.: US 2014/0111221 A1
(43) Pub. Date: Apr. 24, 2014

(54) TESTING DEVICE AND METHOD

(71) Applicants: HONG FU JIN PRECISION INDUSTRY (SHENZHEN) CO., LTD, Shenzhen (CN); HON HAI PRECISION INDUSTRY CO., LTD., New Taipei (TW)

(72) Inventors: YA-GUO WANG, Shenzhen (CN); CHUN-CHING CHEN, New Taipei (TW)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/866,197

(22) Filed: Apr. 19, 2013

(30) Foreign Application Priority Data
Oct. 23, 2012 (CN) 2012104050053

(51) Int. Cl. G01R 31/28

(52) U.S. Cl. CPC G01R 31/28
USPC 324/537

(57) ABSTRACT

A testing method tests the performance of a disc loading and transferring mechanism having a tray. The testing method includes steps of transmitting tray-out and tray-in instructions in that order, to drive the tray between a closed position and an opened position, detecting when the tray reaches the opposing position, counting the number of operations of the tray alternating between a closed position and an opened position; determining when the number of counts is equal to a predetermined number and outputting test results when the actual count is equal to a predetermined number or when the count is interrupted by malfunction.

### BACKGROUND

1. Technical Field

The present disclosure relates to testing technology, particular to a testing device and a testing method for testing a traverse module.

2. Description of Related Art

A traverse module is a major component of a disc drive. The traverse module includes a disc loading and transferring mechanism. The life of the disc loading and transferring mechanism affects the quality of the traverse module. Therefore, during production of the disc drive, the disc loading and transferring mechanism needs to be tested. However, the method for testing the disc loading and transferring mechanism is to manually drive tray of the disc inwards and outwards, to load and eject, this takes an inordinate amount of the tester's time.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic view of a disc loading and transferring mechanism when the disc loading and transferring mechanism is in a closed state.

FIG. 2 is a schematic view of the disc loading and transferring mechanism of FIG. 1 when the disc loading and transferring mechanism is in an opened state.

FIG. 3 is a schematic view of the disc loading and transferring mechanism of FIG. 1 during a tray of the disc loading and transferring mechanism moves inward or moves outward.

FIG. 4 is a function block diagram of the disc loading and transferring mechanism of FIG. 1.

FIG. 5 is a schematic view a graphic user interface (GUI) provide by the disc loading and transferring mechanism of FIG. 1.

FIG. 6 is a chart of a testing result provide by the disc loading and transferring mechanism of FIG. 1.

FIG. 7 is a flow chart of a testing method for testing the disc loading and transferring mechanism.

### DETAILED DESCRIPTION

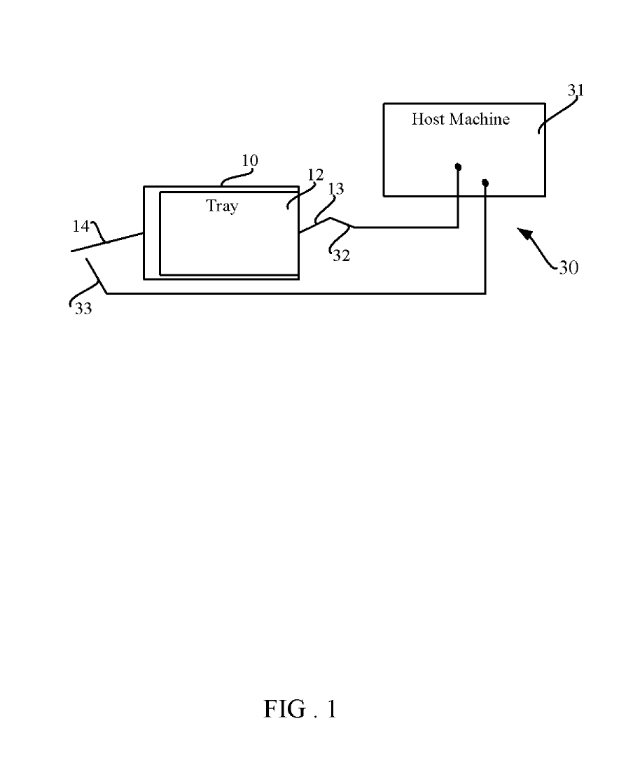

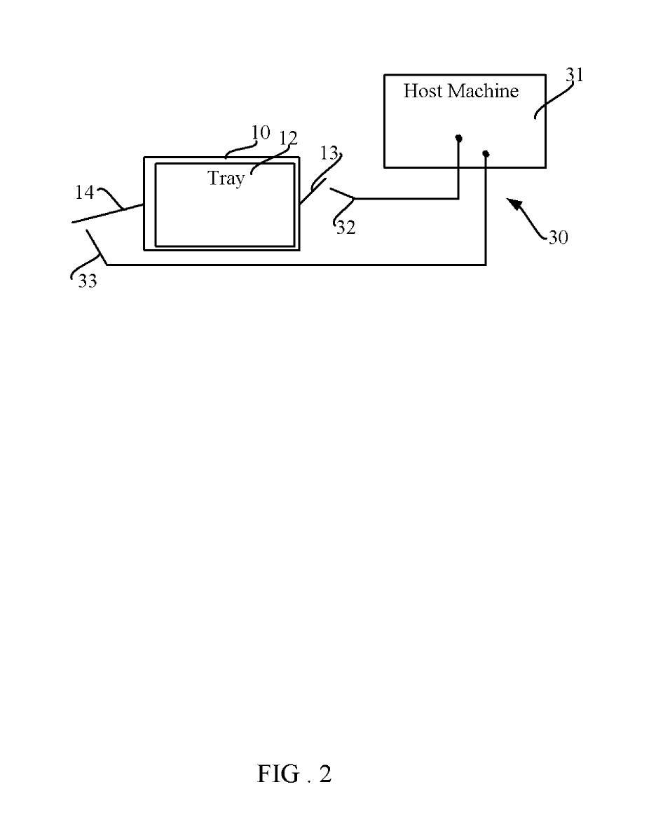

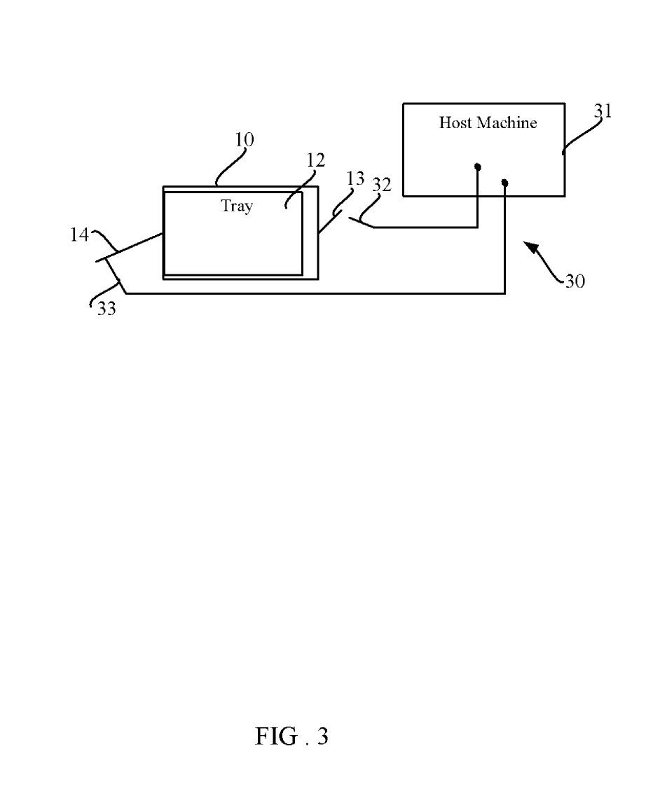

Referring to FIGS. 1-3, a testing device 30 is configured to test a disc loading and transferring mechanism 10. The disc loading and transferring mechanism 10 includes a transferring member (not shown), a tray 12, a first limiting switch 13, and a second limiting switch 14. The tray 12 is loaded with a disc (not shown). The transferring member drives the tray 12 to move inward to reach a closed and loaded position, and to move the disc loading and transferring mechanism 10 outward to reach an opened position. The first limiting switch 13 is activated when the tray 12 reaches the closed position, when the disc loading and transferring mechanism 10 is in a closed state. The second limiting switch 14 is activated when the tray 12 reaches the opened position, when the disc loading and transferring mechanism 10 is in an opened state. In this embodiment, an original state of the disc loading and transferring mechanism 10 is the closed state. In other words, the first limiting switch 13 is activated, and the second limiting switch 14 is not activated.

The testing device 30 includes a host machine 31, a first testing pin 32, and a second testing pin 33. The first testing pin 32 and the second testing pin 33 are configured to detect the respective states of the first limiting switch 13 and the second limiting switch 14, and generate a first detecting signal and a second detecting signal based on the respective states of the first limiting switch 13 and the second limiting switch 14. In this embodiment, the first testing pin 32 contacts the first limiting switch 13 when the first limiting switch 13 is activated, and the first detecting signal is a first predetermined voltage, such as a digital-high voltage. The first testing pin 32 separates from first limiting switch 13 when the first limiting switch 13 is deactivated, and the second detecting signal is a second predetermined voltage, such a digital-low voltage. Similarly, the second testing pin 32 contacts the second limiting switch 14 when the second limiting switch 14 is activated, and the third detecting signal is a third predetermined voltage, such as a digital-high voltage. The second testing pin 33 separates from the second limiting switch 14 when the second limiting switch 14 is deactivated, and the fourth detecting signal is a fourth predetermined voltage, such as a digital-low voltage. Thus when the disc loading and transferring mechanism 10 is in the original closed state, the first detecting signal is the first predetermined voltage, and the second detecting signal is the fourth predetermined voltage.

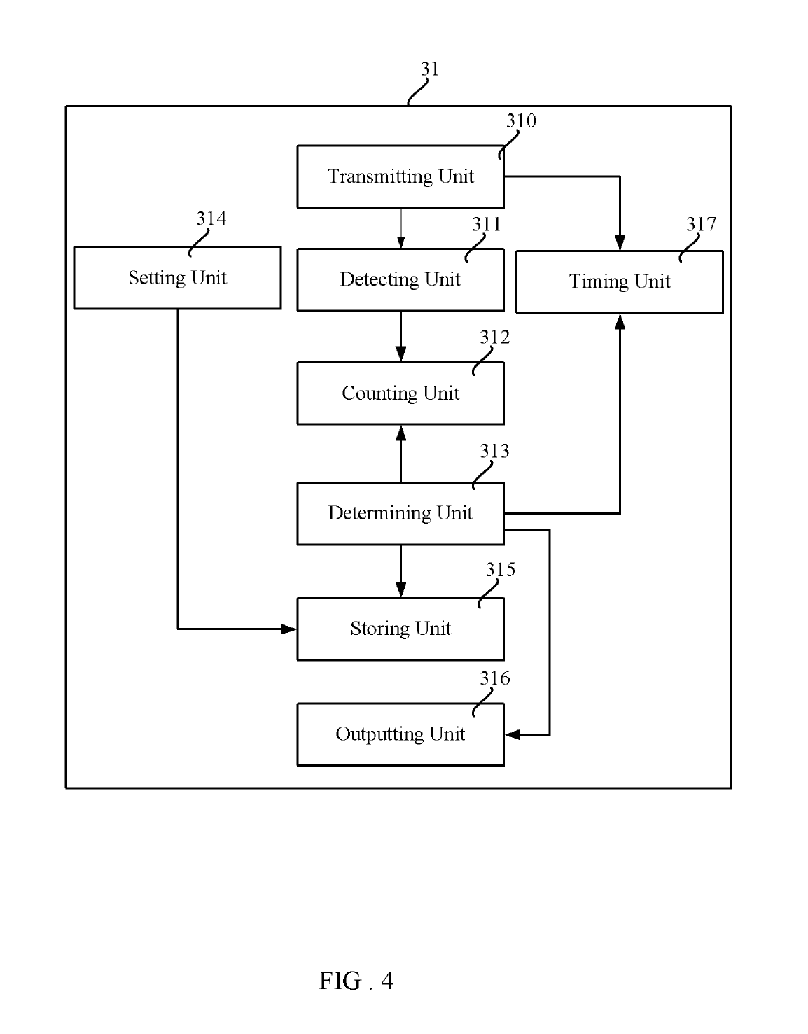

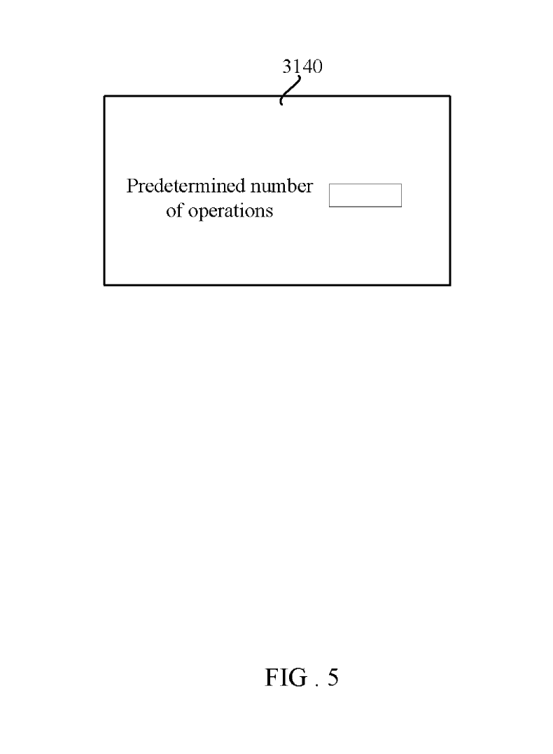

Referring to FIGS. 4 and 5, the host machine 31 includes a transmitting unit 310, a detecting unit 311, a counting unit 312, a determining unit 313, a setting unit 314, a storing unit 315, an output unit 315, and a timing unit 317.

The setting unit 314 provides a graphic user interface (GUI) 3140 to enable a user to set a predetermined number of operations B and store the predetermined number in the storing unit 315. In this embodiment, the predetermined number of operations B is 10000.

When the testing device 30 is started up, the transmitting unit 310 transmits a tray-out instruction to the disc loading and transferring mechanism 10 to drive the tray 12 to move outward, and transmits a first timing instruction to the timing unit 317, and transmits a first detecting instruction to the detecting unit 311. In the embodiment, the transmitting unit 310 transmits the tray-out instruction to the disc loading and transferring mechanism 10 wirelessly or via wires.

The timing unit 317 begins to count a first time period of the tray moving from the closed positioned to the opened position in response to the first timing instruction.

The detecting unit 311 detects when the tray 12 reaches the opened position in response to the first detecting instruction. In particular, the detecting unit 311 detects whether the tray 12 reaches the opened position by detecting the voltages of the first detecting signal and the second detecting signal. The detecting unit 311 generates a first control instruction when the first detecting signal and the second detecting signal are second predetermined voltage and the third predetermined voltage when the tray 12 reaches the opened state. Otherwise, the detecting unit 311 generates a determining signal when the first detecting signal or the second deterring signal is not the second predetermined voltage or the third predetermined voltage.

In response to the first control instruction, the transmitting unit 310 transmits a tray-in instruction to the disc loading and transferring mechanism 10 to drive the tray 12 inward, and transmits a second detecting instruction to the detecting unit 311, and a second timing instruction to the timing unit 317.

The timing unit 317 ends the counting of the first time period and begins to count a second time period, of the tray 12 moving from the opened position to the closed position, in response to the second timing instruction.

In response to the second detecting instruction, the detecting unit 311 detects when the tray 12 has reached the closed position. In particular, the detecting unit 311 detects when the tray 12 has reached the closed position by detecting the voltages of the first detecting signal and the second detecting signal. The detecting unit 311 generates a second control instruction and a counting instruction when the first detecting signal and the second detecting signal are the first predetermined voltage and the fourth predetermined voltage when the tray 12 reaches the closed position. The detecting unit 311 generates the determining instruction when the first detecting signal or the second detecting signal is not the first predetermined voltage or the fourth predetermined voltage when the tray 12 reaches the closed position.

The counting unit 312 counts an actual number of operations A in response to the counting instruction. In this embodiment, the actual number of the operations A begins at 0, and an increment of one is added to the operations A after the counting unit 312 has counted one operation. In the embodiment, the tray moves from the closed position to the opened position, one operation is recorded.

The determining unit 313 determines whether the first and the second periods of counting respectively reach a first predetermined time period and a second predetermined time period, and generates a stop instruction when either the first period of counting or the second period of counting reaches the respective ends of the first and the second predetermined time periods. The determining unit 313 further determines when the accumulated number of the operations A has reached the predetermined number of the operations B, and generates a stop instruction when the accumulated number of operations A has incremented to the predetermined number of the operations B. In the embodiment, the first predetermined time period is different from the second predetermined time period.

The timing unit 317 stops counting in response to a stop instruction.

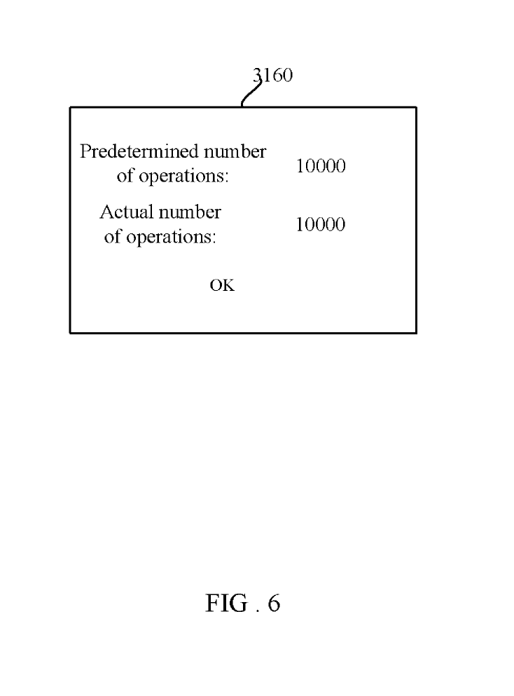

Referring to FIG. 6, the output unit 316 outputs test results 3160 in response to a stop instruction. The test results 3160 show the predetermined number of operations B, the accumulated number of operations A, and an indication as to whether or not the disc loading and transferring mechanism 10 is in conformity or is not in conformity with predetermined and expected standards.

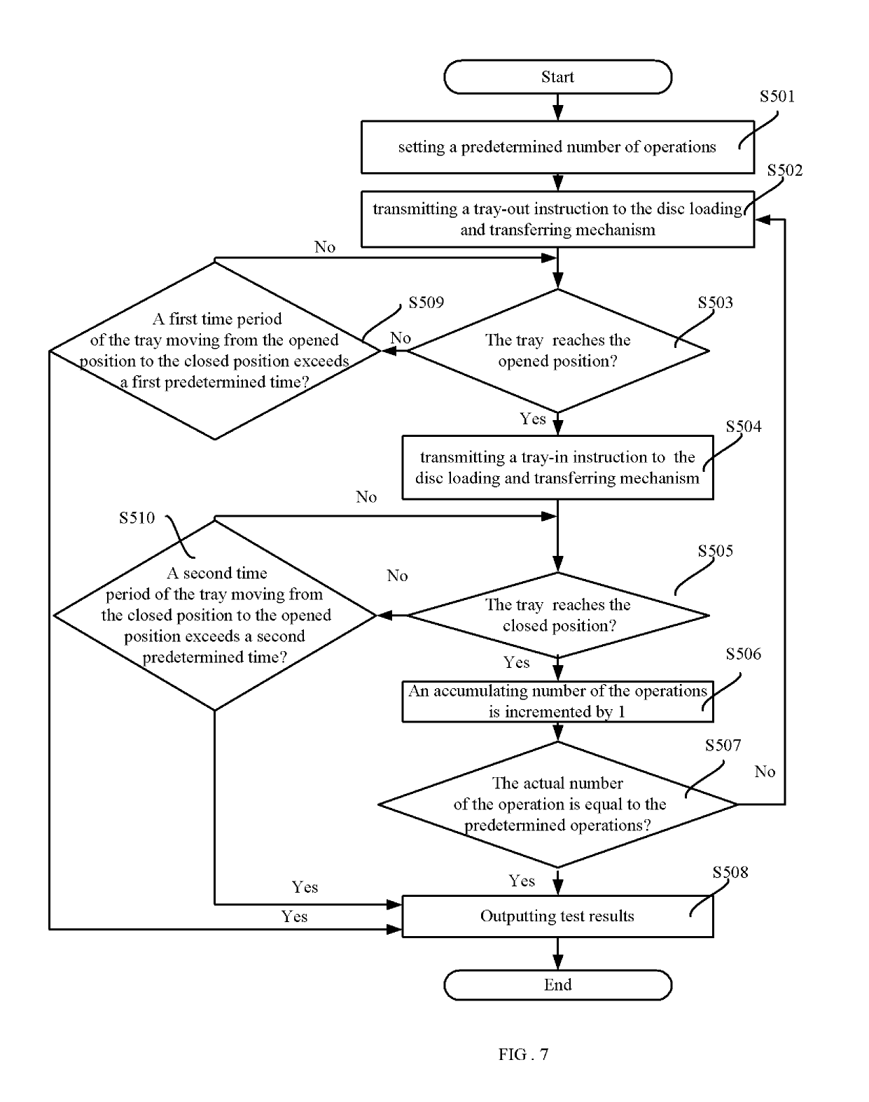

Referring to FIGS. 1-3 and 7, a testing method for testing the disc loading and transferring mechanism 10 is applied to the testing device 30. The disc loading and transferring mechanism 10 includes a transferring member (not shown), a tray 12, a first limiting switch 13, and a second limiting switch 14. The tray 12 is configured to carry and load a disc (not shown). The transferring mechanism of the disc loading and transferring mechanism 10 drives the tray 12 inward to reach a closed position, and moves the disc outward to reach an opened position. The first limiting switch 13 is activated when the tray 12 is in the closed position indicating that the disc loading and transferring mechanism 10 is in a closed state. The second limiting switch 14 is activated when the tray 12 reaches the opened position indicating that the disc loading and transferring mechanism 10 is in an opened state. The testing method includes the following steps:

In step S501, setting the staring number of operations as 0, and setting a predetermined number of operations. In this embodiment, the predetermined number of operations is 10000.

In step S502, transmitting a tray-out instruction to the disc loading and transferring mechanism 10 to drive the tray 12 out toward the opened position.

In step S503, detecting when the tray 12 reaches the opened position. The process goes to step S504 when the tray 12 does reach the opened position. The process goes to step S509, when the tray 12 does not reach the opened position. In this embodiment, a first testing pin 32 and a second testing pin 33 are provided for contact or non-contact with the first testing pin 32 and the second testing pin 32 to detect when the tray 12 reaches the opened position. In particular, the first testing pin 33 contacts the first limiting switch 13 to generate a first predetermined voltage as a first detecting signal when the first limiting switch 13 is activated. A first detecting signal of a second predetermined voltage is generated when the first testing pin 33 separates from and deactivates the first limiting switch 13. Similarly, the second limiting switch 14 is activated when the second testing pin 34 makes contact with the second limiting switch 14, and a second detecting signal of a third predetermined voltage is thereby generated. When the second testing pin 34 is separated from the second limiting switch 14, the second limiting switch 14 is deactivated such that a second detecting signal of a fourth predetermined voltage is generated. In this embodiment, the first predetermined voltage and the third predetermined voltage are digital-high voltages. The second predetermined voltage and the fourth predetermined voltage are digital-low voltages. The first detecting signal of the second predetermined voltage, and the second detecting signal of the third predetermined voltage are detected when the tray 12 has reached the opened state.

In step S504, transmitting a tray-in instruction to drive the tray 12 inward to the closed position.

In step S505, detecting when the tray 12 reaches the closed position. The process goes to step S506 when the tray 12 reaches the closed position. The process goes to step S510 when the tray 12 does not reach the closed position. In particular, the tray 12 is determined to be in the closed position when the first detecting signal of the first predetermined voltage and the second detecting signal of the fourth predetermined voltage are detected.

In step S506, the accumulating number of the operations is incremented by 1.

In step S507, determining when the accumulating number of the operations reaches the predetermined number of the operations. The process goes to step S508 when the accumulating number of the operations reaches the predetermined number. The process goes to step S502 if the accumulating number of the operations has not reached the predetermined number of operations.

In step S508, outputting test results. The test results show the predetermined number of the operations, the accumulating number of the operations, and an indication as to whether or not the disc loading and transferring mechanism 10 is in conformity or is not in conformity with a standard.

In step S509, determining whether a first time period of the tray moving from the opened position to the closed position exceeds a first predetermined time. The process goes to step S503 if the length of the first time period does not exceed the length of the first predetermined time period. The process goes to step S508 if the first predetermined time period ends as the first time period is still running.

In step S510, determining whether a second time period of the tray 12 moving from the closed position to the opened position exceeds a second predetermined time period. The process goes to step S505 if the second time period finishes before a second predetermined time period. The process goes to step S508 when the second time period is still running when the second predetermined time period finishes.

Even though relevant information and the advantages of the present embodiments have been set forth in the foregoing description, together with details of the functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. A testing device for testing a disc loading and transferring mechanism, the loading and transferring mechanism comprises a tray for loading a disc, the testing device comprising:
a transmitting unit to transmit a tray-out signal and a tray-in signal in that order to control the tray to alternate between a closed position and a opened position;
a detecting unit to detect whether the tray reaches the closed position and the opened position, and generates a counting instruction after the tray reaches the opened position and the closed position;
a counting unit to count an actual number of the operations of the tray alternating between a closed position and a opened position in response to the counting instruction;
a determining unit to determine whether the number of the counting operations is equal to a predetermined number of operations, and generates a stop instruction when the number of the counting operations is equal to a predetermined number of operations; and
an outputting unit to output test results in response to the stop instruction.

2. The testing device of claim 1, wherein the testing device further comprising a host machine, a first testing pin and a second testing pin, the host machine configured to detecting whether the tray reaches the opened position and the closed position via the first testing pin and the second testing pin.

3. The testing device of claim 1, wherein the disc loading and transferring mechanism comprises a first limiting switch, and a second limiting switch, the first limiting switch is activated to contact with the first testing pin when the tray reaches the opened position, and the first limiting switch separates from the first testing pin when the tray do not reach the opened position; the second limiting switch is activated to contact with the second testing pin when the tray reaches the closed position, and the second limiting switch separates from the second testing pin when the tray do not reach the closed position, the first testing pin generates a first detecting signal with a first predetermined voltage when contacting with the first limiting switch, and generates the first detecting signal with a second predetermined voltage difference from the first predetermined voltage when separating from the first limiting switch; the second testing pin generates a second detecting signal with a third predetermined voltage when contacting with the second limiting switch, and generates the second detecting signal with a fourth predetermined voltage different from the third predetermined voltage when separating from the second limiting switch.

4. The testing device of claim 3, wherein the host machine comprises a detecting unit, the detecting unit configured to detect whether the tray reaches the opened position and the closed position by detecting voltages of the first detecting signal and the second detecting signal.

5. The testing device of claim 1, further comprising a timing unit, the timing unit being configured to count a first time period of the tray moving from the closed positioned to the opened position, and counting a second time period of the tray moving from the opened position to the closed position, the determining unit being further configured to determine whether the first time period exceeds a first predetermined time period or the second time period exceeds a second predetermined time period, and generates the stop instruction to control the outputting unit to output the testing results when the first time period exceeds a first predetermined time period or the second time period exceeds a second predetermined time period.

6. A testing method for testing a disc loading and transferring mechanism having a tray, the testing method comprising steps of:
transmitting a tray-out instruction and a tray-in instruction in that order to drive the tray to alternate between a closed position and an opened position;
detecting whether the tray reaches the closed position and the opened position;
counting an actual number of the operations of the tray alternating between a closed position and a opened position when the tray reaches the closed position and the opened position;
determine whether the number of the counting operations is equal to a predetermined number of operations; and
outputting testing results when the number of the counting operations is equal to a predetermined number of operations.

7. The testing method of claim 6, wherein detecting whether the tray reaches the closed position and the opened position by following steps:
providing a first testing pin which contacts with the disc loading and transferring device to generate a first detecting signal of a first predetermined voltage when the tray reaches the closed state, and separates from the disc loading and transferring device to generate the first detecting signal of a second predetermined voltage when the tray does not reach the closed state;
providing a second testing pin which contacts with the disc loading and transferring device to generate a second detecting signal of a third predetermined voltage when the tray reaches the opened position and separates from the disc loading and transferring device, and generate a second detecting signal of a fourth predetermined voltage when the tray does not reach the opened state; and
detecting the voltages of the detecting signal and the second detecting signal so as to determined whether the tray reaches the opened position and the closed position.

8. The testing method of claim 7, wherein the first detecting signal is detected to be the first predetermined voltage, and the second detecting signal is detected to be the fourth predetermined voltage when the tray reaches the closed position; the first detecting signal is detected to be the second predetermined voltage, and the second detecting signal is detected to be the third predetermined voltage that the tray reaches the opened position.

9. The testing method of claim 7, wherein the first testing pin contacts with or separates from a first limiting switch of the disc loading and transferring mechanism; the second testing pin contacts with or separates from a second limiting switch of the disc loading and transferring mechanism.

10. The testing method of claim 6, further comprising following steps after transmitting the tray-out instruction to the disc loading and transferring mechanism:
counting a first time period of the tray moving from the closed position to the opened position;
determining whether the first time period exceeds a first predetermined time period; and
outputting the testing results when the first time period exceeds the first predetermined time period.

11. The testing method of claim 6, further comprising following steps after transmitting the tray-in instruction to the disc loading and transferring mechanism:
counting a second time period of the tray moving from the opened position to the closed position;
determining whether the second time period exceeds a second predetermined time period; and
outputting the testing results when the second time period exceeds the second predetermined time period.
